(19) United States
(12) Patent Application Publication
(10) Pub. No.: US 2016/0079328 A1
(43) Pub. Date: Mar. 17, 2016

(54) THIN FILM TRANSISTOR SUBSTRATE AND DISPLAY APPARATUS

(71) Applicant: Samsung Display Co., Ltd., Yongin-City (KR)

(72) Inventors: Shinhyuk Yang, Yongin-City (KR); Eunhyun Kim, Yongin-City (KR); Taeyoung Kim, Yongin-City (KR); Hyehyang Park, Yongin-City (KR)

(21) Appl. No.: 14/615,210

(22) Filed: Feb. 5, 2015

(30) Foreign Application Priority Data
Sep. 15, 2014 (KR) 10-2014-0122045

(51) Int. Cl. H01L 27/32; H01L 29/786

(52) U.S. Cl. CPC H01L 27/3262; H01L 27/322; H01L 27/3248; H01L 27/3258; H01L 29/7869

(57) ABSTRACT

Provided is a thin film transistor substrate including a substrate; a source electrode and a drain electrode that are disposed on the substrate; an active layer that is formed on the source electrode and the drain electrode; a gate electrode that is formed on and is insulated from the active layer; and a pixel electrode that extends from one of the source electrode and the drain electrode.

### CLAIM OF PRIORITY

This application claims the priority and all the benefits accruing under 35 U.S.C. §119 of Korean Patent Application No. 10-2014-0122045, filed on Sep. 15, 2014, in the Korean Intellectual Property Office (“KIPO”), the disclosure of which is incorporated herein in its entirety by reference.

### BACKGROUND OF THE INVENTION

1. Field of the Invention

One or more embodiments relate to a thin film transistor substrate and a display apparatus.

2. Description of the Related Art

Recently, display apparatuses are variously used. Also, as the display apparatuses have a small thickness and a light weight, a usage range of the display apparatuses becomes wide.

In particular, recently, display apparatuses have been replaced with portable thin flat panel display apparatuses.

The thin display apparatus may include at least one thin film transistor so as to receive an electrical signal for an electric operation.

The thin film transistor may affect an electrical characteristic of the display apparatus and thus may affect an image quality of the display apparatus.

Also, since the thin film transistor includes a plurality of members, a plurality of processes are required for the manufacture of the thin film transistor, so that the thin film transistor may affect improving overall manufacturing efficiency of the display apparatus.

### SUMMARY OF THE INVENTION

One or more exemplary embodiments include a thin film transistor substrate and a display apparatus.

Additional aspects will be set forth in part in the description which follows and, in part, will be apparent from the description, or may be learned by practice of the presented embodiments.

According to one or more exemplary embodiments, a thin film transistor substrate includes a substrate; a source electrode and a drain electrode that are disposed on the substrate; an active layer that is formed on the source electrode and the drain electrode; a gate electrode that is formed on and is insulated from the active layer; and a pixel electrode that extends from one of the source electrode and the drain electrode.

The thin film transistor substrate may further include an auxiliary electrode that is electrically connected to one of the source electrode and the drain electrode.

The auxiliary electrode may contact a top surface of one of the source electrode and the drain electrode.

The auxiliary electrode may be formed of a material having a lower resistivity than the source electrode and the drain electrode.

The auxiliary electrode may be separate from the active layer.

The thin film transistor substrate may further include a first insulating layer disposed on the gate electrode, and the auxiliary electrode may be disposed on the first insulating layer.

The thin film transistor substrate may further include a protective layer that is formed on a surface of the active layer that faces the gate electrode.

The thin film transistor substrate may further include a photo-protective layer that is disposed between the active layer and the substrate and at least partially overlaps the active layer.

The photo-protective layer may be formed of a color filter material.

The thin film transistor substrate may further include a color filter that is disposed between the pixel electrode and the substrate and at least partially overlaps the pixel electrode.

According to one or more exemplary embodiments, a display apparatus includes a substrate; a source electrode and a drain electrode that are disposed on the substrate; an active layer that is formed on the source electrode and the drain electrode; a gate electrode that is formed on and is insulated from the active layer; and a display device that realizes at least one visible light, wherein the display device includes a pixel electrode that extends from one of the source electrode and the drain electrode.

The display apparatus may further include an auxiliary electrode that is electrically connected to one of the source electrode and the drain electrode.

The display apparatus may further include a protective layer that is formed on a surface of the active layer that faces the gate electrode.

The display apparatus may further include a photo-protective layer that is disposed between the active layer and the substrate and at least partially overlaps the active layer.

The display apparatus may further include a color filter that is disposed between the pixel electrode and the substrate and at least partially overlaps the pixel electrode.

The display device may include an opposite electrode that faces the pixel electrode; and an intermediate layer that is disposed between the pixel electrode and the opposite electrode and includes an organic emission layer.

According to one or more exemplary embodiments, a display apparatus includes a plurality of pixels that are formed on a substrate, wherein each of the plurality of pixels includes a thin-film transistor and a display device that realizes at least one visible light, wherein the thin-film transistor includes a source electrode and a drain electrode; an active layer that is formed on the source electrode and the drain electrode; and a gate electrode that is formed on and is insulated from the active layer, and wherein the display device includes a pixel electrode that extends from one of the source electrode and the drain electrode.

The display device includes an opposite electrode that faces the pixel electrode; and an intermediate layer that is disposed between the pixel electrode and the opposite electrode and includes an organic emission layer.

The organic emission layer of the intermediate layer may be commonly formed in two adjacent pixels from among the plurality of pixels.

The intermediate layer may generate visible light that is common with respect to the plurality of pixels.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a thin film transistor substrate according to an embodiment;

FIG. 2 is a cross-sectional view of a thin film transistor substrate, according to another embodiment;

FIG. 3 is a cross-sectional view of a thin film transistor substrate, according to another embodiment;

FIG. 4 is a cross-sectional view of a thin film transistor substrate, according to another embodiment;

FIG. 5 is a cross-sectional view of a thin film transistor substrate, according to another embodiment;

FIG. 6 is a cross-sectional view of a thin film transistor substrate, according to another embodiment;

FIG. 7 is a cross-sectional view of a thin film transistor substrate, according to another embodiment;

FIG. 8 is a cross-sectional view of a display apparatus, according to an embodiment;

FIG. 9 is a cross-sectional view of a display apparatus, according to another embodiment;

FIG. 10 is a cross-sectional view of a display apparatus, according to another embodiment;

FIG. 10 is a cross-sectional view of a display apparatus, according to another embodiment;

FIG. 11 is a cross-sectional view of a display apparatus, according to another embodiment; and

FIG. 12 is a schematic view illustrating a modified example of the display apparatus of FIG. 11.

### DETAILED DESCRIPTION OF THE INVENTION

As the inventive concept allows for various changes and numerous embodiments, particular embodiments will be illustrated in the drawings and described in detail in the written description. Effects and features of the inventive concept and methods of accomplishing the same may be understood more readily by reference to the following detailed description of preferred embodiments and the accompanying drawings. The inventive concept may, however, be embodied in many different forms and should not be construed as being limited to the embodiments set forth herein.

Hereinafter, one or more embodiments will be described below in more detail with reference to the accompanying drawings. Those components that are the same or are in correspondence are rendered the same reference numeral regardless of the figure number, and redundant explanations are omitted.

Hereinafter, in one or more embodiments, while such terms as “first,” “second,” etc., may be used, but such components must not be limited to the above terms, and the above terms are used only to distinguish one component from another.

Hereinafter, in one or more embodiments, a singular form may include plural forms, unless there is a particular description contrary thereto.

Hereinafter, in one or more embodiments, terms such as “comprise” or “comprising” are used to specify existence of a recited feature or component, not excluding the existence of one or more other recited features or one or more other components.

Hereinafter, in one or more embodiments, it will also be understood that when an element such as layer, region, or component is referred to as being “on” another element, it can be directly on the other element, or intervening elements such as layer, region, or component may also be interposed therebetween.

In the drawings, for convenience of description, the sizes of layers and regions are exaggerated for clarity. For example, a size and thickness of each element may be random for convenience of description, thus, one or more embodiments are not limited thereto.

Hereinafter, in one or more embodiments, X-axis, Y-axis, and Z-axis may not be limited to three axes on a rectangular coordinate system but may be interpreted as a broad meaning including the three axes. For example, the X-axis, Y-axis, and Z-axis may be perpendicular to each other or may indicate different directions that are not perpendicular to each other.

In one or more embodiments, an order of processes may be different from that is described. For example, two processes that are sequentially described may be substantially simultaneously performed, or may be performed in an opposite order to the described order.

Expressions such as “at least one of,” when preceding a list of elements, modify the entire list of elements and do not modify the individual elements of the list.

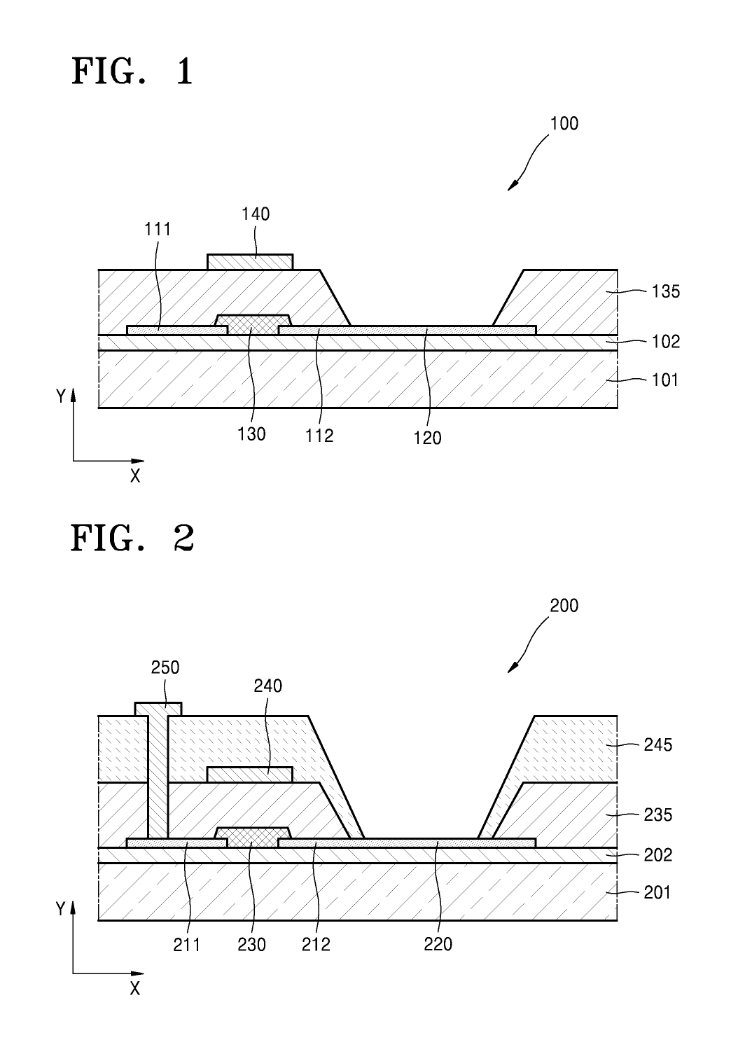

FIG. 1 is a cross-sectional view of a thin film transistor substrate 100 according to an embodiment.

Referring to FIG. 1, the thin film transistor substrate 100 includes a substrate 101, a source electrode 111, a drain electrode 112, an active layer 130, a pixel electrode 120, and a gate electrode 140.

The substrate 101 may be formed of a glass material containing SiO₂ as a main component, but is not limited thereto. Thus, the substrate 101 may be formed of a plastic material. Here, the plastic material for forming the substrate 101 may be selected from various organic materials.

In an embodiment, the substrate 101 may be formed of a metal thin film.

In another embodiment, the substrate 101 may be formed of an organic material. For example, the substrate 101 may include an organic material such as polyimide, polyethylene napthalate, polyethyleneterephthalate (PET), polyarylate, polycarbonate, polyether imide (PEI), or polyethersulfone that has excellent heat-resistance and durability.

A buffer layer 102 may be formed on the substrate 101. The buffer layer 102 may block foreign substances that penetrate via the substrate 101, may provide a planar surface on the substrate 101, and may be formed of various materials capable of performing that function. Since the buffer layer 102 is not an essential element, the buffer layer 102 may not be arranged.

The source electrode 111 and the drain electrode 112 are formed on the buffer layer 102. The source electrode 111 and the drain electrode 112 are formed by having a space arranged therebetween on at least one region.

The source electrode 111 and the drain electrode 112 may be formed of various materials. In more detail, the source electrode 111 and the drain electrode 112 may be formed of a conductive material.

In another embodiment, the source electrode 111 and the drain electrode 112 may include Mo or Ti.

In another embodiment, the source electrode 111 and the drain electrode 112 may be formed of a light-transmitting material. For example, the source electrode 111 and the drain electrode 112 may include at least one material selected from the group of light-transmitting materials including indium tin oxide (ITO), indium zinc oxide (IZO), zinc oxide (ZnO), indium oxide (In₂O₃), indium gallium oxide (IGO), and aluminum zinc oxide (AZO).

The pixel electrode 120 is formed on the buffer layer 102. The pixel electrode 120 extends from at least one of the source electrode 111 and the drain electrode 112. That is, the pixel electrode 120 may be formed of a same material as one of the source electrode 111 and the drain electrode 112 and may be integrally formed with one of the source electrode 111 and the drain electrode 112.

In another embodiment, the pixel electrode 120 lengthwise extends from at least one of the source electrode 111 and the drain electrode 112.

In the present embodiment, the pixel electrode 120 lengthwise extends from the drain electrode 112. In another embodiment, the pixel electrode 120 may extend from the source electrode 111.

The active layer 130 is formed on the source electrode 111 and the drain electrode 112. That is, the active layer 130 is formed to correspond to the space between the source electrode 111 and the drain electrode 112.

In another embodiment, the active layer 130 may be formed while contacting the source electrode 111 and the drain electrode 112, and in particular, the active layer 130 may contact side surfaces of the source electrode 111 and the drain electrode 112 that face each other. For example, the active layer 130 may contact the side surface of the source electrode 111 that faces the drain electrode 112, and may contact the side surface of the drain electrode 112 that faces the source electrode 111.

In another embodiment, the active layer 130 may be formed while contacting regions of top surfaces of the source electrode 111 and the drain electrode 112.

The active layer 130 may be formed of various materials, e.g., the active layer 130 may include an oxide semiconductor material. In an embodiment, the active layer 130 may include ZnO-based oxide. In another embodiment, the active layer 130 may be formed of an oxide semiconductor material including In, Ga, or Sn.

In another embodiment, the active layer 130 may include G—I—Z—ORIn₂O₃)a(Ga₂O₃)b(ZnO)c] (where, a, b, c are real numbers that satisfy a≧0, b≧0, c≧0, respectively).

In another embodiment, the active layer 130 may include oxide including a material selected from metal elements of groups 12, 13, and 14 consisting of zinc (Zn), indium (In), gallium (Ga), tin (Sn), cadmium (Cd), germanium (Ge), and hafnium (Hf), and a composition thereof.

In another embodiment, the active layer 130 may include a silicon-based inorganic semiconductor material or an organic semiconductor material.

The gate electrode 140 is formed to have a region overlapping a portion of the active layer 130. That is, the gate electrode 140 and the active layer 130 at least partly overlap each other. The gate electrode 140 may be formed of various materials having excellent conductivity. In another embodiment, the gate electrode 140 may be formed of low-resistive metal material including molybdenum (Mo), aluminum (Al), copper (Cu), or titanium (Ti).

In another embodiment, the gate electrode 140 may include a single layer formed of a material having excellent conductivity or may include multiple layers including a material having excellent conductivity.

A first insulating layer 135 is formed between the gate electrode 140 and the active layer 130. The first insulating layer 135 electrically insulates the gate electrode 140 from the active layer 130. In more detail, the first insulating layer 135 is formed on the source electrode 111, the drain electrode 112, and the active layer 130. Here, the first insulating layer 135 may be formed to cover the active layer 130.

The first insulating layer 135 may not cover at least a portion of the pixel electrode 120. In another embodiment, the first insulating layer 135 may cover at least a portion of a side of the pixel electrode 120.

The gate electrode 140 is formed on the first insulating layer 135. The first insulating layer 135 may be formed of various insulating materials, for an example, an inorganic material such as silicon oxide, silicon nitride, or aluminum oxide, or for another example, a polymer organic material.

In the present embodiment, the thin film transistor substrate 100 is formed in a manner that the source electrode 111 and the drain electrode 112 are formed on the substrate 101, and the pixel electrode 120 extends from any one of the source electrode 111 and the drain electrode 112. That is, since the pixel electrode 120 is formed of the same material as the source electrode 111 and the drain electrode 112, manufacturing efficiency may be improved.

Also, the source electrode 111, the drain electrode 112, and the pixel electrode 120 may be formed of the light-transmitting material, and by doing so, light may pass through the pixel electrode 120, thus, it is easy to embody the thin film transistor substrate 100 that is appropriate for a display apparatus that realizes an image toward the substrate 101.

Also, since the source electrode 111 and the drain electrode 112 are formed on the substrate 101, and the active layer 130 is formed on the source electrode 111 and the drain electrode 112, overlapping regions or contact regions between the active layer 130 and the source electrode 111 and the drain electrode 112 are increased, so that a short channel structure may be easily implemented. By doing so, the thin film transistor substrate 100 that is appropriate for the high definition display apparatus may be easily embodied.

FIG. 2 is a cross-sectional view of a thin film transistor substrate 200, according to another embodiment.

Referring to FIG. 2, the thin film transistor substrate 200 includes a substrate 201, a source electrode 211, a drain electrode 212, an active layer 230, a pixel electrode 220, a gate electrode 240, and an auxiliary electrode 250. For convenience of description, the present embodiment will be described in consideration of features different from those of the previous embodiment.

A material of the substrate 201 is the same as that described in the previous embodiment, thus, detailed descriptions thereof are omitted here.

A buffer layer 202 may be formed on the substrate 201 but is not an essential element and thus may be omitted.

The source electrode 211 and the drain electrode 212 are formed on the buffer layer 202. The source electrode 211 and the drain electrode 212 are formed by having a space arranged therebetween on at least one region.

Materials of the source electrode 211 and the drain electrode 212 are the same as those described in the previous embodiment, thus, detailed descriptions thereof are omitted here. That is, as in the previous embodiment, the source electrode 211 and the drain electrode 212 may be formed of a light-transmitting material.

The pixel electrode 220 is formed on the buffer layer 202. The pixel electrode 220 extends from at least one of the source electrode 211 and the drain electrode 212. That is, the pixel electrode 220 may be formed of a same material as one of the source electrode 211 and the drain electrode 212 and may be integrally formed with one of the source electrode 211 and the drain electrode 212. In another embodiment, the pixel electrode 220 lengthwise extends from at least one of the source electrode 211 and the drain electrode 212.

In the present embodiment, the pixel electrode 220 lengthwise extends from the drain electrode 212. In another embodiment, the pixel electrode 220 may lengthwise extend from the source electrode 211.

The active layer 230 is formed on the source electrode 211 and the drain electrode 212. That is, the active layer 230 is formed to correspond to the space between the source electrode 211 and the drain electrode 212.

The features including various structures of the active layer 230 are the same as those described in the previous embodiment, thus, detailed descriptions thereof are omitted here.

The active layer 230 may be formed of various materials, e.g., the active layer 230 may include an oxide semiconductor material. The descriptions about the various materials that form the active layer 230 are the same as those described in the previous embodiment, thus, detailed descriptions thereof are omitted here.

The gate electrode 240 is formed to have a region overlapping a portion of the active layer 230. That is, the gate electrode 240 and the active layer 230 partly overlap each other.

A first insulating layer 235 is formed between the gate electrode 240 and the active layer 230. The first insulating layer 235 electrically insulates the gate electrode 240 from the active layer 230. In more detail, the first insulating layer 235 is formed on the source electrode 211, the drain electrode 212, and the active layer 230. Here, the first insulating layer 235 may be formed to cover the active layer 230.

The first insulating layer 235 may not cover at least a portion of the pixel electrode 220. In another embodiment, the first insulating layer 235 may cover at least a portion of a side of the pixel electrode 220.

The gate electrode 240 is formed on the first insulating layer 235.

A second insulating layer 245 is formed on the gate electrode 240. The second insulating layer 245 is formed to cover the gate electrode 240. The second insulating layer 245 is formed on the first insulating layer 235. The second insulating layer 245 does not cover at least a portion of the pixel electrode 220.

In an embodiment, the second insulating layer 245 may cover the first insulating layer 235 in a region corresponding to a top surface of the pixel electrode 220.

In another embodiment, at least a portion of the first insulating layer 235 is not covered with the second insulating layer 245 but is exposed in a region corresponding to a top surface of the pixel electrode 220.

The auxiliary electrode 250 is formed on the second insulating layer 245. The auxiliary electrode 250 contacts at least one of the source electrode 211 and the drain electrode 212. The first insulating layer 235 and the second insulating layer 245 are formed to expose at least a portion of any one of the source electrode 211 and the drain electrode 212, and the auxiliary electrode 250 may contact the exposed portion.

Here, the auxiliary electrode 250 may not correspond to a region of the pixel electrode 220 that is not covered with the first insulating layer 235 and the second insulating layer 245.

In another embodiment, the auxiliary electrode 250 may be separate from the pixel electrode 220.

The auxiliary electrode 250 improves an electrical characteristic of the source electrode 211 and the drain electrode 212. In particular, when the source electrode 211 and the drain electrode 212 are formed of a light-transmitting material, electrical resistance of the source electrode 211 and the drain electrode 212 may be improved, and in this regard, the high electrical resistance may be complemented by forming the auxiliary electrode 250 by using a low-resistive material.

The auxiliary electrode 250 may be formed of various conductive materials, e.g., a metal material having excellent conductivity.

Also, the auxiliary electrode 250 may be formed of a material of which resistivity is lower than the source electrode 211 and the drain electrode 212.

In an embodiment, the auxiliary electrode 250 may include Cu, Ag, Al, Mo, or Au.

Also, in another embodiment, the auxiliary electrode 250 is separate from the active layer 230, so that it is possible to prevent that a component of the auxiliary electrode 250 propagates to the active layer 230 and damages the active layer 230.

In the present embodiment, the auxiliary electrode 250 and the gate electrode 240 are formed on different layers, i.e., the auxiliary electrode 250 is formed on the second insulating layer 245, so that an interference between the auxiliary electrode 250 and the gate electrode 240 may be minimized, and the auxiliary electrode 250 and the gate electrode 240 may be finely patterned.

However, in an embodiment, the auxiliary electrode 250 may be formed on the first insulating layer 235, i.e., the auxiliary electrode 250 and the gate electrode 240 may be formed on a same layer.

In the present embodiment, the thin film transistor substrate 200 is formed in a manner that the source electrode 211 and the drain electrode 212 are formed on the substrate 201, and the pixel electrode 220 extends from any one of the source electrode 211 and the drain electrode 212. That is, since the pixel electrode 220 is formed of a same material as the source electrode 211 and the drain electrode 212, manufacturing efficiency may be improved.

Also, the source electrode 211, the drain electrode 212, and the pixel electrode 220 may be formed of the light-transmitting material, and by doing so, light may pass through the pixel electrode 220, thus, it is easy to embody the thin film transistor substrate 200 that is appropriate for a display apparatus that realizes an image toward the substrate 201.

Also, since the auxiliary electrode 250 is formed to be electrically connected to one of the source electrode 211 and the drain electrode 212, an electrical characteristic of the source electrode 211 and the drain electrode 212 may be improved, and the thin film transistor substrate 200 having an excellent electrical characteristic may be easily embodied.

Also, since the source electrode 211 and the drain electrode 212 are formed on the substrate 201, and the active layer 230 is formed on the source electrode 211 and the drain electrode 212, overlapping regions or contact regions between the active layer 230 and the source electrode 211 and the drain electrode 212 are increased, so that a short channel structure may be easily implemented. By doing so, the thin film transistor substrate 200 that is appropriate for the high definition display apparatus may be easily embodied.

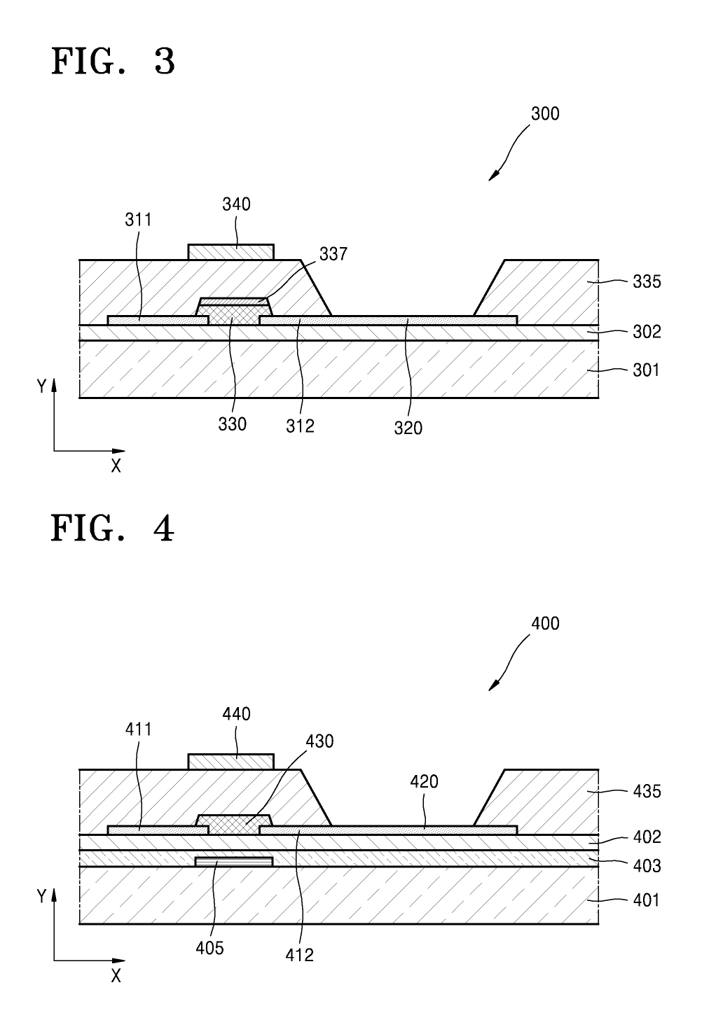

FIG. 3 is a cross-sectional view of a thin film transistor substrate 300, according to another embodiment.

Referring to FIG. 3, the thin film transistor substrate 300 includes a substrate 301, a source electrode 311, a drain electrode 312, an active layer 330, a pixel electrode 320, a gate electrode 340, and a protective layer 337.

The gate electrode 340 may be formed on a first insulating layer 335.

For convenience of description, the present embodiment will be described in consideration of features different from those of the previous embodiment.

The protective layer 337 is formed on a top surface of the active layer 330. That is, the protective layer 337 is formed on a surface of the active layer 330 that faces the gate electrode 340.

The protective layer 337 may be formed of various materials.

In an embodiment, the protective layer 337 may be formed of various insulating materials.

In the present embodiment, the thin film transistor substrate 300 has a structure in which the protective layer 337 is formed on the top surface of the active layer 330, and thus may prevent impurities or other foreign substances from penetrating into the active layer 330.

By doing so, the thin film transistor substrate 300 having an improved electrical characteristic may be easily embodied.

The features including various structures and effects of the thin film transistor substrate 300 are the same as those described in the previous embodiment, thus, detailed descriptions thereof are omitted here.

An auxiliary electrode shown in FIG. 2 may be further formed in the thin film transistor substrate 300 of the present embodiment.

FIG. 4 is a cross-sectional view of a thin film transistor substrate 400, according to another embodiment.

Referring to FIG. 4, the thin film transistor substrate 400 includes a substrate 401, a source electrode 411, a drain electrode 412, an active layer 430, a pixel electrode 420, a gate electrode 440, and a photo-protective layer 405. The gate electrode 440 may be formed on a first insulating layer 435.

For convenience of description, the present embodiment will be described in consideration of features different from those of the previous embodiment.

The photo-protective layer 405 may correspond to the active layer 430. The photo-protective layer 405 may face a surface of the active layer 430 that is opposite to another surface of the active layer 430 that faces the gate electrode 440.

In an embodiment, the photo-protective layer 405 may be disposed between the substrate 401 and the active layer 430.

In another embodiment, the photo-protective layer 405 may overlap at least a portion of a surface of the active layer 430 that does not correspond to the source electrode 411 and the drain electrode 412.

In another embodiment, an over-coated layer 403 may be formed on the substrate 401 so as to cover the photo-protective layer 405. The over-coated layer 403 may be formed below the buffer layer 402.

The photo-protective layer 405 may decrease or prevent that light that is externally incident via the substrate 401 affects the active layer 430. To do so, the photo-protective layer 405 may be formed of a material capable of blocking at least a portion of light.

In another embodiment, the photo-protective layer 405 may be a black matrix.

In another embodiment, the photo-protective layer 405 may be formed of a color filter material, e.g., a red color filter material. In particular, when the active layer 430 is formed of an oxide semiconductor material, the active layer 430 is less affected by light having a red-based wavelength, and thus, if the photo-protective layer 405 is formed of the red color filter material, light may appropriately be blocked.

In the present embodiment, the thin film transistor substrate 400 may prevent, by arranging the photo-protective layer 405, the active layer 430 from being damaged by light, so that the thin film transistor substrate 400 having an improved electrical characteristic may be easily embodied.

The features including various structures and effects of the thin film transistor substrate 400 are the same as those described in the previous embodiment, thus, detailed descriptions thereof are omitted here.

An auxiliary electrode shown in FIG. 2 or a protective layer shown in FIG. 3 may be further formed in the thin film transistor substrate 400 of the present embodiment.

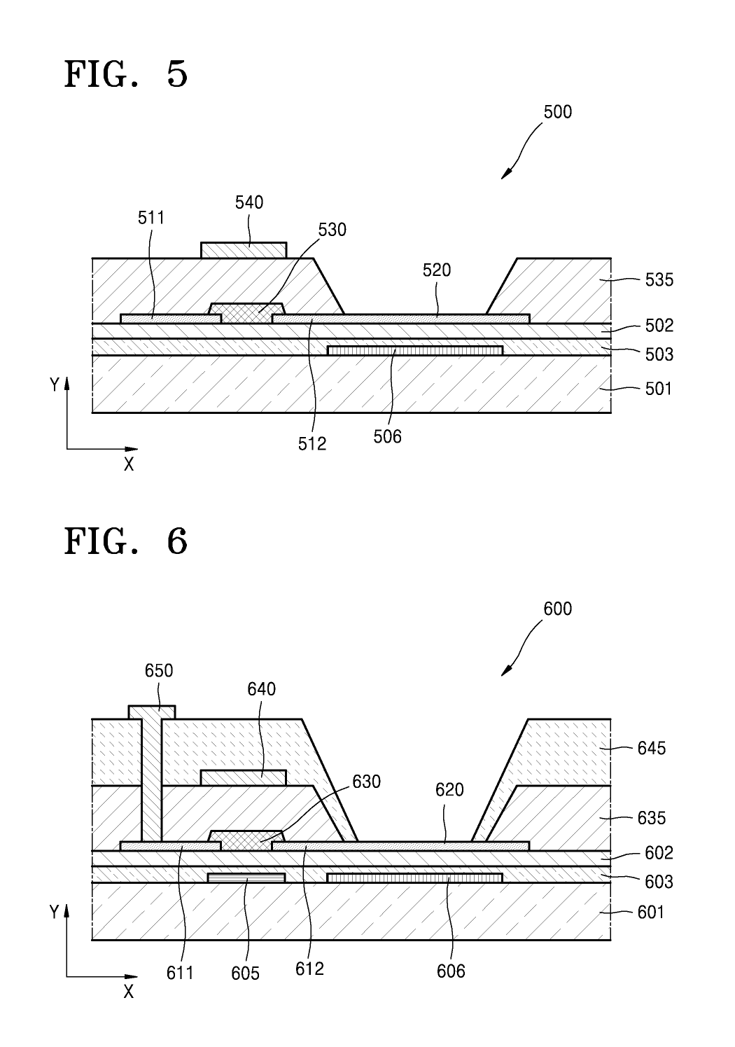

FIG. 5 is a cross-sectional view of a thin film transistor substrate 500, according to another embodiment.

Referring to FIG. 5, the thin film transistor substrate 500 includes a substrate 501, a source electrode 511, a drain electrode 512, an active layer 530, a pixel electrode 520, a gate electrode 540, and a color filter 506. The gate electrode 540 may be formed on a first insulating layer 535.

For convenience of description, the present embodiment will be described in consideration of features different from those of the previous embodiment.

The color filter 506 may correspond to at least a portion of the pixel electrode 520. In more detail, the color filter 506 may correspond to the portion of the pixel electrode 520 that is not covered with the first insulating layer 535.

The color filter 506 may be disposed between the pixel electrode 520 and the substrate 501.

In an embodiment, an over-coated layer 503 may be formed on the substrate 501 so as to cover the color filter 506. The over-coated layer 503 may be formed below the buffer layer 502.

The color filter 506 may be formed to correspond to the pixel electrode 520, so that it is easy to embody the thin film transistor substrate 500 that is appropriate for a display apparatus capable of realizing various colors.

The features including various structures and effects of the thin film transistor substrate 500 are the same as those described in the previous embodiment, thus, detailed descriptions thereof are omitted here.

An auxiliary electrode shown in FIG. 2 or a protective layer shown in FIG. 3 may be further formed in the thin film transistor substrate 500 of the present embodiment. Also, a photo-protective layer shown in FIG. 4 may be further formed in the thin film transistor substrate 500 of the present embodiment.

FIG. 6 is a cross-sectional view of a thin film transistor substrate 600, according to another embodiment.

Referring to FIG. 6, the thin film transistor substrate 600 includes a substrate 601, a source electrode 611, a drain electrode 612, an active layer 630, a pixel electrode 620, a gate electrode 640, an auxiliary electrode 650, a photo-protective layer 605, and a color filter 606. The gate electrode 640 may be formed on a first insulating layer 635. A buffer layer 602 may be formed on the substrate 601 but is not an essential element and thus may be omitted.

For convenience of description, the present embodiment will be described in consideration of features different from those of the previous embodiment.

The auxiliary electrode 650 is formed on a second insulating layer 645.

The photo-protective layer 605 may correspond to the active layer 630. The photo-protective layer 605 may face a surface of the active layer 630 that is opposite to another surface of the active layer 630 that faces the gate electrode 640.

In an embodiment, an over-coated layer 603 may be formed on the substrate 601 so as to cover the photo-protective layer 605. The over-coated layer 603 may be formed below the buffer layer 602.

The color filter 606 may correspond to at least a portion of the pixel electrode 620. In more detail, the color filter 606 may correspond to the portion of the pixel electrode 620 that is not covered with the first insulating layer 635.

The color filter 606 may be disposed between the pixel electrode 620 and the substrate 601.

In an embodiment, the color filter 606 may be formed on the substrate 601, and the over-coated layer 603 may be formed to cover the color filter 606. The over-coated layer 603 may be formed below the buffer layer 602.

The color filter 606 may be formed to correspond to the pixel electrode 620, so that it is easy to embody the thin film transistor substrate 600 that is appropriate for a display apparatus capable of realizing various colors.

When the color filter 606 is formed, the photo-protective layer 605 may be simultaneously formed by using a red color filter material. That is, after the photo-protective layer 605 and the color filter 606 are formed on the substrate 601, the over-coated layer 603 may be formed to cover the photo-protective layer 605 and the color filter 606.

By doing so, manufacturing efficiency of the thin film transistor substrate 600 may be improved.

The features including various structures and effects of the thin film transistor substrate 600 are the same as those described in the previous embodiment, thus, detailed descriptions thereof are omitted here.

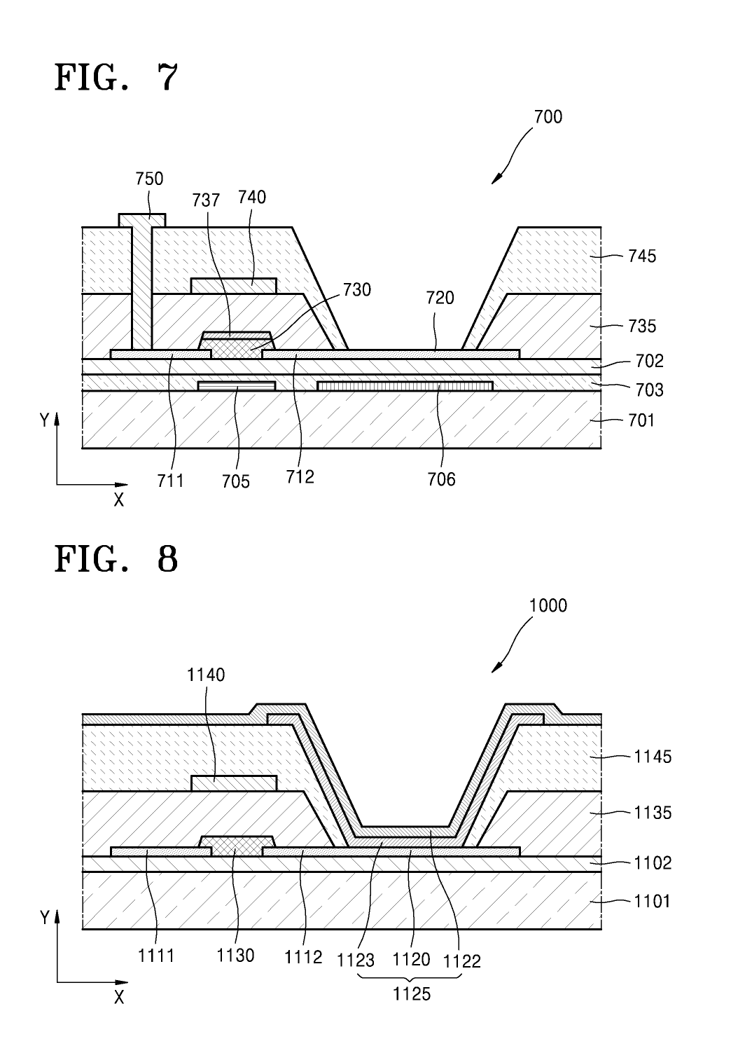

FIG. 7 is a cross-sectional view of a thin film transistor substrate 700, according to another embodiment.

Referring to FIG. 7, the thin film transistor substrate 700 includes a substrate 701, a source electrode 711, a drain electrode 712, an active layer 730, a protective layer 737, a pixel electrode 720, a gate electrode 740, an auxiliary electrode 750, a photo-protective layer 705, and a color filter 706. The gate electrode 740 may be formed on a first insulating layer 735. A buffer layer 702 may be formed on the substrate 701 but is not an essential element and thus may be omitted.

For convenience of description, the present embodiment will be described in consideration of features different from those of the previous embodiment.

The protective layer 737 is formed on a top surface of the active layer 730. That is, the protective layer 737 is formed on a surface of the active layer 730 that faces the gate electrode 740.

The auxiliary electrode 750 is formed on a second insulating layer 745.

The photo-protective layer 705 is formed to correspond to the active layer 730. The photo-protective layer 705 may face a surface of the active layer 730 that is opposite to another surface of the active layer 730 that faces the gate electrode 740.

In an embodiment, an over-coated layer 703 may be formed on the substrate 701 so as to cover the photo-protective layer 705. The over-coated layer 703 may be formed below the buffer layer 702.

The color filter 706 may correspond to at least a portion of the pixel electrode 720. In more detail, the color filter 706 may correspond to the portion of the pixel electrode 720 that is not covered with the first insulating layer 735.

The color filter 706 may be disposed between the pixel electrode 720 and the substrate 701.

In an embodiment, the over-coated layer 703 may be formed on the substrate 701 so as to cover the color filter 706. The over-coated layer 703 may be formed below the buffer layer 702.

The color filter 706 may be formed to correspond to the pixel electrode 720, so that it is easy to embody the thin film transistor substrate 700 that is appropriate for a display apparatus capable of realizing various colors.

When the color filter 706 is formed, the photo-protective layer 705 may be simultaneously formed by using a red color filter material. That is, after the photo-protective layer 705 and the color filter 706 are formed on the substrate 701, the over-coated layer 703 may be formed to cover the photo-protective layer 705 and the color filter 706.

By doing so, manufacturing efficiency of the thin film transistor substrate 700 may be improved.

The features including various structures and effects of the thin film transistor substrate 700 are the same as those described in the previous embodiment, thus, detailed descriptions thereof are omitted here.

FIG. 8 is a cross-sectional view of a display apparatus 1000, according to an embodiment.

Referring to FIG. 8, the display apparatus 1000 includes a substrate 1101, a source electrode 1111, a drain electrode 1112, an active layer 1130, an organic light-emitting device 1125 including a pixel electrode 1120, and a gate electrode 1140.

The display apparatus 1000 of FIG. 8 is an organic light-emitting display apparatus and includes the organic light-emitting device 1125 as a display device.

However, the present embodiment is not limited thereto and may include various types of a display device including a liquid crystal device or the like.

The substrate 1101 may be formed of a glass material containing SiO₂ as a main component, but is not limited thereto. Thus, the substrate 1101 may be formed of a plastic material. Here, the plastic material for forming the substrate 1101 may be selected from various organic materials.

In an embodiment, the substrate 1101 may be formed of a metal thin film.

In another embodiment, the substrate 1101 may be formed of an organic material. For example, the substrate 1101 may include an organic material such as polyimide, polyethylene napthalate, polyethyleneterephthalate (PET), polyarylate, polycarbonate, polyether imide (PEI), or polyethersulfone that has excellent heat-resistance and durability.

A buffer layer 1102 may be formed on the substrate 1101. The buffer layer 1102 may block foreign substances that penetrate via the substrate 1101, may provide a planar surface on the substrate 1101, and may be formed of various materials capable of performing that function. Since the buffer layer 1102 is not an essential element, the buffer layer 1102 may not be arranged.

The source electrode 1111 and the drain electrode 1112 are formed on the buffer layer 1102. The source electrode 1111 and the drain electrode 1112 are formed by having a space arranged therebetween on at least one region.

The source electrode 1111 and the drain electrode 1112 may be formed of various materials. In more detail, the source electrode 1111 and the drain electrode 1112 may be formed of a conductive material.

In another embodiment, the source electrode 1111 and the drain electrode 1112 may include Mo or Ti.

In another embodiment, the source electrode 1111 and the drain electrode 1112 may be formed of a light-transmitting material. For example, the source electrode 1111 and the drain electrode 1112 may include at least one material selected from the group of light-transmitting materials including indium tin oxide (ITO), indium zinc oxide (IZO), zinc oxide (ZnO), indium oxide (In₂O₃), indium gallium oxide (IGO), and aluminum zinc oxide (AZO).

The pixel electrode 1120 is formed on the buffer layer 1102. The pixel electrode 1120 extends from at least one of the source electrode 1111 and the drain electrode 1112. That is, the pixel electrode 1120 may be formed of a same material as one of the source electrode 1111 and the drain electrode 1112 and may be integrally formed with one of the source electrode 1111 and the drain electrode 1112. In another embodiment, the pixel electrode 1120 lengthwise extends from at least one of the source electrode 1111 and the drain electrode 1112.

In the present embodiment, the pixel electrode 1120 lengthwise extends from the drain electrode 1112. In another embodiment, the pixel electrode 1120 may extend from the source electrode 1111.

The active layer 1130 is formed on the source electrode 1111 and the drain electrode 1112. That is, the active layer 1130 is formed to correspond to the space between the source electrode 1111 and the drain electrode 1112.

In another embodiment, the active layer 1130 may be formed while contacting the source electrode 1111 and the drain electrode 1112, and in particular, the active layer 1130 may contact side surfaces of the source electrode 1111 and the drain electrode 1112 that face each other. For example, the active layer 1130 may contact the side surface of the source electrode 1111 that faces the drain electrode 1112, and may contact the side surface of the drain electrode 1112 that faces the source electrode 1111.

In another embodiment, the active layer 1130 may be formed while contacting regions of top surfaces of the source electrode 1111 and the drain electrode 1112.

The active layer 1130 may be formed of various materials, e.g., the active layer 1130 may include an oxide semiconductor material. In an embodiment, the active layer 1130 may include ZnO-based oxide. In another embodiment, the active layer 1130 may be formed of an oxide semiconductor material including In, Ga, or Sn.

In another embodiment, the active layer 1130 may include G—I—Z—ORIn₂O₃)a(Ga₂O₃)b(ZnO)c] (where, a, b, c are real numbers that satisfy a≧0, b≧0, c≧0, respectively).

In another embodiment, the active layer 1130 may include oxide including a material selected from metal elements of groups 12, 13, and 14 consisting of zinc (Zn), indium (In), gallium (Ga), tin (Sn), cadmium (Cd), germanium (Ge), and hafnium (Hf), and a composition thereof.

In another embodiment, the active layer 1130 may include a silicon-based inorganic semiconductor material or an organic semiconductor material.

The gate electrode 1140 is formed to have a region overlapping a portion of the active layer 1130. That is, the gate electrode 1140 and the active layer 1130 partly overlap each other. The gate electrode 1140 may be formed of various materials having excellent conductivity. In another embodiment, the gate electrode 1140 may be formed of low-resistive metal material including molybdenum (Mo), aluminum (Al), copper (Cu), or titanium (Ti).

In another embodiment, the gate electrode 1140 may include a single layer formed of a material having excellent conductivity or may include multiple layers including a material having excellent conductivity.

A first insulating layer 1135 is formed between the gate electrode 1140 and the active layer 1130. The first insulating layer 1135 electrically insulates the gate electrode 1140 from the active layer 1130. In more detail, the first insulating layer 1135 is formed on the source electrode 1111, the drain electrode 1112, and the active layer 1130. Here, the first insulating layer 1135 may be formed to cover the active layer 1130.

The first insulating layer 1135 may not cover at least a portion of the pixel electrode 1120. In another embodiment, the first insulating layer 1135 may cover at least a portion of a side of the pixel electrode 1120.

The gate electrode 1140 is formed on the first insulating layer 1135. The first insulating layer 1135 may be formed of various insulating materials, for an example, an inorganic material such as silicon oxide, silicon nitride, or aluminum oxide, or for another example, a polymer organic material.

A second insulating layer 1145 is formed on the gate electrode 1140. The second insulating layer 1145 is formed to cover the gate electrode 1140. The second insulating layer 1145 is formed on a first insulating layer 1135. The second insulating layer 1145 does not cover at least a portion of the pixel electrode 1120.

In an embodiment, the second insulating layer 1145 may cover the first insulating layer 1135 in a region corresponding to a top surface of the pixel electrode 1120.

In another embodiment, at least a portion of the first insulating layer 1135 is not covered with the second insulating layer 1145 but is exposed in a region corresponding to a top surface of the pixel electrode 1120.

An intermediate layer 1123 is formed on the top surface of the pixel electrode 1120. The intermediate layer 1123 may include an organic emission layer so as to generate a visible ray. Colors of light that is generated by the intermediate layer 1123 may vary. That is, the colors may include red color, green color, blue color, or the like. In another embodiment, the intermediate layer 1123 may generate white color.

An opposite electrode 1122 is formed on the intermediate layer 1123. The opposite electrode 1122 may be formed of various conductive materials including lithium (Li), calcium (Ca), fluoride lithium/calcium (LiF/Ca), fluoride lithium/aluminum (LiF/Al), aluminum (Al), magnesium (Mg), or silver (Ag).

In the present embodiment, the display apparatus 1000 may have a structure in which the source electrode 1111 and the drain electrode 1112 are formed on the substrate 1101, and the pixel electrode 1120 extends from any one of the source electrode 1111 and the drain electrode 1112. That is, since the pixel electrode 1120 is formed of a same material as the source electrode 1111 and the drain electrode 1112, manufacturing efficiency may be improved.

Also, the source electrode 1111, the drain electrode 1112, and the pixel electrode 1120 may be formed of the light-transmitting material, and by doing so, light may pass through the pixel electrode 1120, thus, the display apparatus 1000 that realizes an image toward the substrate 1101 may be easily embodied.

Also, since the source electrode 1111 and the drain electrode 1112 are formed on the substrate 1101, and the active layer 1130 is formed on the source electrode 1111 and the drain electrode 1112, overlapping regions or contact regions between the active layer 1130 and the source electrode 1111 and the drain electrode 1112 are increased, so that a short channel structure may be easily implemented. By doing so, the display apparatus 1000 having high definition may be easily embodied.

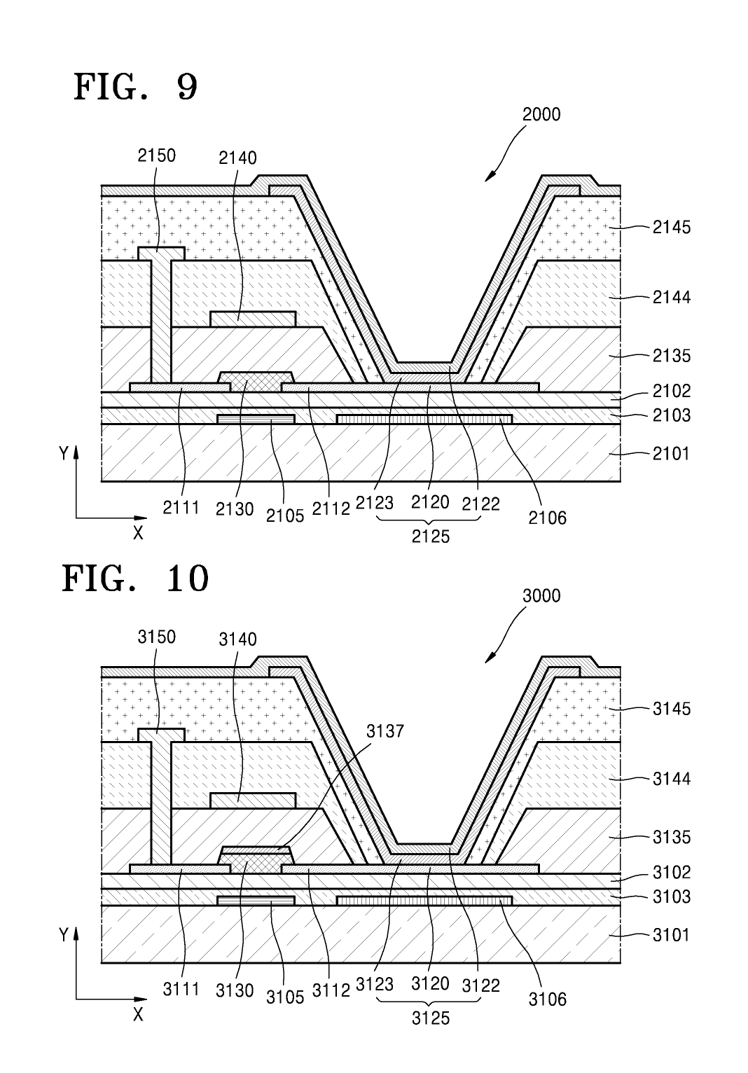

FIG. 9 is a cross-sectional view of a display apparatus 2000, according to another embodiment.

Referring to FIG. 9, the display apparatus 2000 includes a substrate 2101, a source electrode 2111, a drain electrode 2112, an active layer 2130, an organic light-emitting device 2125 including a pixel electrode 2120, a gate electrode 2140, a photo-protective layer 2105, a color filter 2106, and an auxiliary electrode 2150.

For convenience of description, the present embodiment will be described in consideration of features different from those of the previous embodiment.

The display apparatus 2000 of FIG. 9 is an organic light-emitting display apparatus and includes the organic light-emitting device 2125 as a display device.

However, the present embodiment is not limited thereto and may include various types of a display device including a liquid crystal device or the like.

The substrate 2101 may be formed of a same material described in the previous embodiment.

A buffer layer 2102 may be formed on the substrate 2101. Since the buffer layer 2102 is not an essential element, the buffer layer 2102 may not be arranged.

The source electrode 2111 and the drain electrode 2112 are formed on the buffer layer 2102. The source electrode 2111 and the drain electrode 2112 may be formed of various materials.

The pixel electrode 2120 is formed on the buffer layer 2102. The pixel electrode 2120 extends from at least one of the source electrode 2111 and the drain electrode 2112. That is, the pixel electrode 2120 may be formed of a same material as one of the source electrode 2111 and the drain electrode 2112 and may be integrally formed with one of the source electrode 2111 and the drain electrode 2112. In another embodiment, the pixel electrode 2120 lengthwise extends from at least one of the source electrode 2111 and the drain electrode 2112.

In the present embodiment, the pixel electrode 2120 lengthwise extends from the drain electrode 2112. In another embodiment, the pixel electrode 2120 may extend from the source electrode 2111.

The active layer 2130 is formed on the source electrode 2111 and the drain electrode 2112. That is, the active layer 2130 is formed to correspond to a space between the source electrode 2111 and the drain electrode 2112.

In another embodiment, the active layer 2130 may be formed while contacting the source electrode 2111 and the drain electrode 2112, and in particular, the active layer 2130 may contact side surfaces of the source electrode 2111 and the drain electrode 2112 that face each other. For example, the active layer 2130 may contact the side surface of the source electrode 2111 that faces the drain electrode 2112, and may contact the side surface of the drain electrode 2112 that faces the source electrode 2111.

In another embodiment, the active layer 2130 may be formed while contacting regions of top surfaces of the source electrode 2111 and the drain electrode 2112.

The active layer 2130 may be formed of various materials, e.g., the active layer 2130 may include an oxide semiconductor material.

The gate electrode 2140 is formed to have a region overlapping a portion of the active layer 2130. That is, the gate electrode 2140 and the active layer 2130 partly overlap each other. The gate electrode 2140 may be formed of various materials having excellent conductivity. In another embodiment, the gate electrode 2140 may be formed of low-resistive metal material including molybdenum (Mo), aluminum (Al), copper (Cu), or titanium (Ti).

In another embodiment, the gate electrode 2140 may include a single layer formed of a material having excellent conductivity or may include multiple layers including a material having excellent conductivity.

A first insulating layer 2135 is formed between the gate electrode 2140 and the active layer 2130. The first insulating layer 2135 electrically insulates the gate electrode 2140 from the active layer 2130. In more detail, the first insulating layer 2135 is formed on the source electrode 2111, the drain electrode 2112, and the active layer 2130. Here, the first insulating layer 2135 may be formed to cover the active layer 2130.

The first insulating layer 2135 may not cover at least a portion of the pixel electrode 2120. In another embodiment, the first insulating layer 2135 may cover at least a portion of a side of the pixel electrode 2120.

The gate electrode 2140 is formed on the first insulating layer 2135. The first insulating layer 2135 may be formed of various insulating materials, for an example, an inorganic material such as silicon oxide, silicon nitride, or aluminum oxide, or for another example, a polymer organic material.

A second insulating layer 2144 is formed on the gate electrode 2140. The second insulating layer 2144 is formed to cover the gate electrode 2140. The second insulating layer 2144 is formed on a first insulating layer 2135. The second insulating layer 2144 does not cover at least a portion of the pixel electrode 2120.

In an embodiment, the second insulating layer 2144 may cover the first insulating layer 2135 in a region corresponding to a top surface of the pixel electrode 2120.

In another embodiment, at least a portion of the first insulating layer 2135 is not covered with the second insulating layer 2144 but is exposed in a region corresponding to a top surface of the pixel electrode 2120.

The auxiliary electrode 2150 is formed on the second insulating layer 2144. The auxiliary electrode 2150 contacts at least one of the source electrode 2111 and the drain electrode 2112. The first insulating layer 2135 and the second insulating layer 2144 are formed to expose at least a portion of any one of the source electrode 2111 and the drain electrode 2112, and the auxiliary electrode 2150 may contact the exposed portion.

Here, the auxiliary electrode 2150 may not correspond to a region of the pixel electrode 2120 that is not covered with the first insulating layer 2135 and the second insulating layer 2144.

The auxiliary electrode 2150 improves an electrical characteristic of the source electrode 2111 and the drain electrode 2112. In particular, when the source electrode 2111 and the drain electrode 2112 are formed of a light-transmitting material, electrical resistance of the source electrode 2111 and the drain electrode 2112 may be improved, and in this regard, the high electrical resistance may be complemented by forming the auxiliary electrode 2150 by using a low-resistive material.

The auxiliary electrode 2150 may be formed of various conductive materials, e.g., a metal material having excellent conductivity.

Also, the auxiliary electrode 2150 may be formed of a material of which resistivity is lower than the source electrode 2111 and the drain electrode 2112.

In an embodiment, the auxiliary electrode 2150 may include Cu, Ag, Al, Mo, or Au.

Also, in another embodiment, the auxiliary electrode 2150 is separate from the active layer 2130, so that it is possible to prevent that a component of the auxiliary electrode 2150 propagates to the active layer 2130 and damages the active layer 2130.

In the present embodiment, the auxiliary electrode 2150 and the gate electrode 2140 are formed on different layers, i.e., the auxiliary electrode 2150 is formed on the second insulating layer 2144, so that an interference between the auxiliary electrode 2150 and the gate electrode 2140 may be minimized, and the auxiliary electrode 2150 and the gate electrode 2140 may be finely patterned.

However, in an embodiment, the auxiliary electrode 2150 may be formed on the first insulating layer 2135, i.e., the auxiliary electrode 2150 and the gate electrode 2140 may be formed on a same layer.

A third insulating layer 2145 is formed on the second insulating layer 2144. The third insulating layer 2145 covers the auxiliary electrode 2150. The third insulating layer 2145 does not cover at least a portion of the pixel electrode 2120.

In an embodiment, the third insulating layer 2145 may be formed on a portion of a top surface of the pixel electrode 2120 so as to cover the second insulating layer 2144.

In another embodiment, at least a portion of the second insulating layer 2144 may not be covered with the third insulating layer 2145 but may be exposed in a region that corresponds to a portion of the top surface of the pixel electrode 2120.

An intermediate layer 2123 is formed on the top surface of the pixel electrode 2120. The intermediate layer 2123 may include an organic emission layer so as to generate a visible ray. Colors of light that is generated by the intermediate layer 2123 may vary. That is, the colors may include red color, green color, blue color, or the like. In another embodiment, the intermediate layer 2123 may generate white color.

An opposite electrode 2122 is formed on the intermediate layer 2123. The opposite electrode 2122 may be formed of various conductive materials including lithium (Li), calcium (Ca), fluoride lithium/calcium (LiF/Ca), fluoride lithium/aluminum (LiF/Al), aluminum (Al), magnesium (Mg), or silver (Ag).

The photo-protective layer 2105 may correspond to the active layer 2130. The photo-protective layer 2105 may face a surface of the active layer 2130 that is opposite to another surface of the active layer 2130 that faces the gate electrode 2140.

In another embodiment, an over-coated layer 2103 may be formed on the substrate 2101 so as to cover the photo-protective layer 2105. The over-coated layer 2103 may be formed below the buffer layer 2102.

The color filter 2106 may correspond to at least a portion of the pixel electrode 2120. In more detail, the color filter 2106 may correspond to the portion of the pixel electrode 2120 that overlaps the intermediate layer 2123.

The color filter 2106 may be disposed between the pixel electrode 2120 and the substrate 2101.

In an embodiment, the color filter 2106 may be formed on the substrate 2101, and the over-coated layer 2103 may be formed to cover the color filter 2106. The over-coated layer 2103 may be formed below the buffer layer 2102.

The color filter 2106 may be formed to correspond to the pixel electrode 2120, so that the display apparatus 2000 that generates various colors may be easily embodied.

When the color filter 2106 is formed, the photo-protective layer 2105 may be simultaneously formed by using a red color filter material. That is, after the photo-protective layer 2105 and the color filter 2106 are formed on the substrate 2101, the over-coated layer 2103 may be formed to cover the photo-protective layer 2105 and the color filter 2106.

By doing so, manufacturing efficiency of the display apparatus 2000 may be improved.

In the present embodiment, the display apparatus 2000 may have a structure in which the source electrode 2111 and the drain electrode 2112 are formed on the substrate 2101, and the pixel electrode 2120 extends from any one of the source electrode 2111 and the drain electrode 2112. That is, since the pixel electrode 2120 is formed of the same material as the source electrode 2111 and the drain electrode 2112, manufacturing efficiency may be improved.

Also, the source electrode 2111, the drain electrode 2112, and the pixel electrode 2120 may be formed of the light-transmitting material, and by doing so, light may pass through the pixel electrode 2120, thus, the display apparatus 2000 that realizes an image toward the substrate 2101 may be easily embodied.

In the present embodiment, the display apparatus 2000 may prevent, by arranging the photo-protective layer 2105, the active layer 2130 from being damaged by light, so that the display apparatus 2000 having an improved electrical characteristic may be easily embodied.

Also, since the source electrode 2111 and the drain electrode 2112 are formed on the substrate 2101, and the active layer 2130 is formed on the source electrode 2111 and the drain electrode 2112, overlapping regions or contact regions between the active layer 2130 and the source electrode 2111 and the drain electrode 2112 are increased, so that a short channel structure may be easily implemented. By doing so, the display apparatus 2000 having high definition may be easily embodied.

FIG. 10 is a cross-sectional view of a display apparatus 3000, according to another embodiment.

Referring to FIG. 10, the display apparatus 3000 includes a substrate 3101, a source electrode 3111, a drain electrode 3112, an active layer 3130, an organic light-emitting device 3125 including a pixel electrode 3120, a gate electrode 3140, an auxiliary electrode 3150, a photo-protective layer 3105, a color filter 3106, and a protective layer 3137.

Compared to the embodiment of FIG. 9, the embodiment of FIG. 10 further includes the protective layer 3137. For convenience of description, the present embodiment will be described in consideration of features different from those of the previous embodiment.

The display apparatus 3000 of FIG. 10 is an organic light-emitting display apparatus and includes the organic light-emitting device 3125 as a display device.

However, the present embodiment is not limited thereto and may include various types of a display device including a liquid crystal device or the like.

The substrate 3101 may be formed of a same material described in the previous embodiment.

A buffer layer 3102 may be formed on the substrate 3101. Since the buffer layer 3102 is not an essential element, the buffer layer 3102 may not be arranged.

The source electrode 3111 and the drain electrode 3112 are formed on the buffer layer 3102.

The pixel electrode 3120 is formed on the buffer layer 3102. The pixel electrode 3120 extends from at least one of the source electrode 3111 and the drain electrode 3112. That is, the pixel electrode 3120 may be formed of a same material as one of the source electrode 3111 and the drain electrode 3112 and may be integrally formed with one of the source electrode 3111 and the drain electrode 3112. In another embodiment, the pixel electrode 3120 lengthwise extends from at least one of the source electrode 3111 and the drain electrode 3112.

The active layer 3130 is formed on the source electrode 3111 and the drain electrode 3112. The active layer 3130 is formed to correspond to a space between the source electrode 3111 and the drain electrode 3112.

The active layer 3130 may be formed of various materials, e.g., the active layer 3130 may include an oxide semiconductor material.

The protective layer 3137 is formed on a top surface of the active layer 3130. That is, the protective layer 3137 is formed on a surface of the active layer 3130 that faces the gate electrode 3140. The protective layer 3137 may be formed of various materials.

In an embodiment, the protective layer 3137 may be formed of various insulating materials.

The gate electrode 3140 is formed to have a region overlapping a portion of the active layer 3130. That is, the gate electrode 3140 and the active layer 3130 partly overlap each other.

The first insulating layer 3135 is formed between the gate electrode 3140 and the active layer 3130. The first insulating layer 3135 may not cover at least a portion of the pixel electrode 3120.

The gate electrode 3140 is formed on the first insulating layer 3135. A second insulating layer 3144 is formed on the gate electrode 3140. The second insulating layer 3144 is formed to cover the gate electrode 3140. The second insulating layer 3144 is formed on the first insulating layer 3135. The second insulating layer 3144 does not cover at least a portion of the pixel electrode 3120.

In an embodiment, the second insulating layer 3144 may cover the first insulating layer 3135 in a region corresponding to a top surface of the pixel electrode 3120.

In another embodiment, at least a portion of the first insulating layer 3135 is not covered with the second insulating layer 3144 but is exposed in a region corresponding to a top surface of the pixel electrode 3120.

The auxiliary electrode 3150 is formed on the second insulating layer 3144. The auxiliary electrode 3150 contacts at least one of the source electrode 3111 and the drain electrode 3112. The first insulating layer 3135 and the second insulating layer 3144 are formed to expose at least a portion of any one of the source electrode 3111 and the drain electrode 3112, and the auxiliary electrode 3150 may contact the exposed portion.

Here, the auxiliary electrode 3150 may not correspond to a region of the pixel electrode 3120 that is not covered with the first insulating layer 3135 and the second insulating layer 3144.

Also, in another embodiment, the auxiliary electrode 3150 is separate from the active layer 3130, so that it is possible to prevent that a component of the auxiliary electrode 3150 propagates to the active layer 3130 and damages the active layer 3130.

A third insulating layer 3145 is formed on the second insulating layer 3144. The third insulating layer 3145 covers the auxiliary electrode 3150. The third insulating layer 3145 does not cover at least a portion of the pixel electrode 3120.

In an embodiment, the third insulating layer 3145 may be formed on a portion of a top surface of the pixel electrode 3120 so as to cover the second insulating layer 3144.

In another embodiment, at least a portion of the second insulating layer 3144 may not be covered with the third insulating layer 3145 but may be exposed in a region that corresponds to a portion of the top surface of the pixel electrode 3120.

An intermediate layer 3123 is formed on the top surface of the pixel electrode 3120. The intermediate layer 3123 may include an organic emission layer so as to generate a visible ray. Colors of light that is generated by the intermediate layer 3123 may vary. That is, the colors may include red color, green color, blue color, or the like. In another embodiment, the intermediate layer 3123 may generate white color.

An opposite electrode 3122 is formed on the intermediate layer 3123. The opposite electrode 3122 may be formed of various conductive materials.

The photo-protective layer 3105 may correspond to the active layer 3130. The photo-protective layer 3105 may face a surface of the active layer 3130 that is opposite to another surface of the active layer 3130 that faces the gate electrode 3140.

In another embodiment, an over-coated layer 3103 may be formed on the substrate 3101 so as to cover the photo-protective layer 3105. The over-coated layer 3103 may be formed below the buffer layer 3102.

The color filter 3106 may correspond to at least a portion of the pixel electrode 3120. In more detail, the color filter 3106 may correspond to the portion of the pixel electrode 3120 that overlaps the intermediate layer 3123.

The color filter 3106 may be disposed between the pixel electrode 3120 and the substrate 3101.

In an embodiment, the color filter 3106 may be formed on the substrate 3101, and the over-coated layer 3103 may be formed to cover the color filter 3106. The over-coated layer 3103 may be formed below the buffer layer 3102.

The color filter 3106 may be formed to correspond to the pixel electrode 3120, so that the display apparatus 3000 that generates various colors may be easily embodied.

When the color filter 3106 is formed, the photo-protective layer 3105 may be simultaneously formed by using a red color filter material. That is, after the photo-protective layer 3105 and the color filter 3106 are formed on the substrate 3101, the over-coated layer 3103 may be formed to cover the photo-protective layer 3105 and the color filter 3106.

By doing so, manufacturing efficiency of the display apparatus 3000 may be improved.

In the present embodiment, the display apparatus 3000 may have a structure in which the source electrode 3111 and the drain electrode 3112 are formed on the substrate 3101, and the pixel electrode 3120 extends from any one of the source electrode 3111 and the drain electrode 3112. That is, since the pixel electrode 3120 is formed of the same material as the source electrode 3111 and the drain electrode 3112, manufacturing efficiency may be improved.

Also, the source electrode 3111, the drain electrode 3112, and the pixel electrode 3120 may be formed of the light-transmitting material, and by doing so, light may pass through the pixel electrode 3120, thus, the display apparatus 3000 that realizes an image toward the substrate 3101 may be easily embodied.

In the present embodiment, the display apparatus 3000 has a structure in which the protective layer 3137 is formed on the top surface of the active layer 3130, and thus may prevent impurities or other foreign substances from penetrating into the active layer 3130. By doing so, the display apparatus 3000 having an improved electrical characteristic may be easily embodied.

Also, since the auxiliary electrode 3150 is formed to be electrically connected to one of the source electrode 3111 and the drain electrode 3112, an electrical characteristic of the source electrode 3111 and the drain electrode 3112 may be improved, and the display apparatus 3000 having an excellent electrical characteristic may be easily embodied.

In the present embodiment, the display apparatus 3000 may prevent, by arranging the photo-protective layer 3105, the active layer 3130 from being damaged by light, so that the display apparatus 3000 having an improved electrical characteristic may be easily embodied.

Also, since the source electrode 3111 and the drain electrode 3112 are formed on the substrate 3101, and the active layer 3130 is formed on the source electrode 3111 and the drain electrode 3112, overlapping regions or contact regions between the active layer 3130 and the source electrode 3111 and the drain electrode 3112 are increased, so that a short channel structure may be easily implemented. By doing so, the display apparatus 3000 having high definition may be easily embodied.

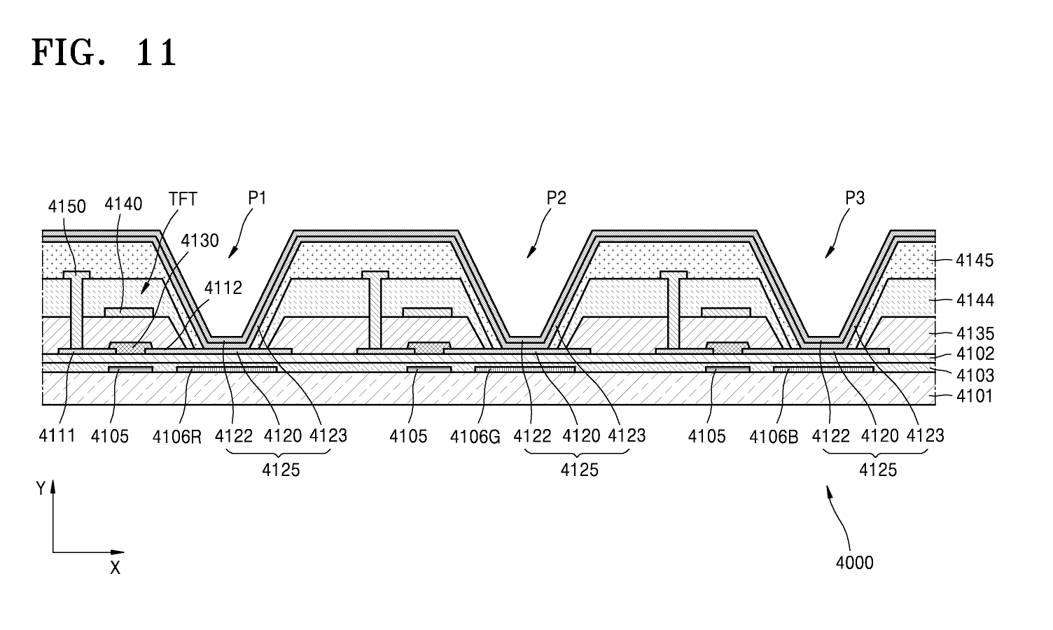

FIG. 11 is a cross-sectional view of a display apparatus 4000, according to another embodiment.

Referring to FIG. 11, the display apparatus 4000 includes a plurality of pixels P1, P2, and P3 on a substrate 4101. Each of the pixels P1, P2, and P3 includes an organic light-emitting device 4125, a color filter (3106R, 3106G, or 3106B), and a thin-film transistor TFT.

The thin-film transistor TFT includes a source electrode 4111, a drain electrode 4112, an active layer 4130, and a gate electrode 4140.

The present embodiment will now be described in detail.

The display apparatus 4000 of FIG. 11 is an organic light-emitting display apparatus and includes the organic light-emitting device 4125 as a display device.

However, the present embodiment is not limited thereto and may include various types of a display device including a liquid crystal device or the like.

The substrate 4101 may be formed of a same material described in the previous embodiment.

A buffer layer 4102 may be formed on the substrate 4101. Since the buffer layer 4102 is not an essential element, the buffer layer 4102 may not be arranged.

The source electrode 4111 and the drain electrode 4112 are formed in each of the pixels P1, P2, and P3 on the buffer layer 4102.

The pixel electrode 4120 is formed in each of the pixels P1, P2, and P3 on the buffer layer 4102. The pixel electrode 4120 extends from at least one of the source electrode 4111 and the drain electrode 4112. That is, the pixel electrode 4120 may be formed of a same material as one of the source electrode 4111 and the drain electrode 4112 and may be integrally formed with one of the source electrode 4111 and the drain electrode 4112. In another embodiment, the pixel electrode 4120 lengthwise extends from at least one of the source electrode 4111 and the drain electrode 4112.

The active layer 4130 is formed in each of the pixels P1, P2, and P3 on the source electrode 4111 and the drain electrode 4112. The active layer 4130 is formed to correspond to a space between the source electrode 4111 and the drain electrode 4112.

The active layer 4130 may be formed of various materials, e.g., the active layer 4130 may include an oxide semiconductor material

Although not illustrated, in another embodiment, a protective layer (not shown) may be formed on a top surface of the active layer 4130.

The gate electrode 4140 is formed to have a region overlapping a portion of the active layer 4130 in each of the pixels P1, P2, and P3. That is, the gate electrode 4140 and the active layer 4130 partly overlap each other.

The first insulating layer 4135 is formed between the gate electrode 4140 and the active layer 4130. The first insulating layer 4135 may not cover at least a portion of the pixel electrode 4120.

The gate electrode 4140 is formed on the first insulating layer 4135. A second insulating layer 4144 is formed on the gate electrode 4140. The second insulating layer 4144 is formed to cover the gate electrode 4140. The second insulating layer 4144 is formed on the first insulating layer 4135. The second insulating layer 4144 does not cover at least a portion of the pixel electrode 4120.

In an embodiment, the second insulating layer 4144 may cover the first insulating layer 4135 in a region corresponding to a top surface of the pixel electrode 4120.

In another embodiment, at least a portion of the first insulating layer 4135 is not covered with the second insulating layer 4144 but is exposed in a region corresponding to a top surface of the pixel electrode 4120.

The auxiliary electrode 4150 is formed on the second insulating layer 4144. The auxiliary electrode 4150 contacts at least one of the source electrode 4111 and the drain electrode 4112. The first insulating layer 4135 and the second insulating layer 4144 are formed to expose at least a portion of any one of the source electrode 4111 and the drain electrode 4112, and the auxiliary electrode 4150 may contact the exposed portion. In an embodiment, the auxiliary electrode 4150 may be formed to correspond to each of the pixels P1, P2, and P3.

Here, the auxiliary electrode 4150 may not correspond to a region of the pixel electrode 4120 that is not covered with the first insulating layer 4135 and the second insulating layer 4144.

Also, in another embodiment, the auxiliary electrode 4150 is separate from the active layer 4130, so that it is possible to prevent that a component of the auxiliary electrode 4150 propagates to the active layer 4130 and damages the active layer 4130.

A third insulating layer 4145 is formed on the second insulating layer 4144. The third insulating layer 4145 covers the auxiliary electrode 4150. The third insulating layer 4145 does not cover at least a portion of the pixel electrode 4120.

In an embodiment, the third insulating layer 4145 may be formed on a portion of a top surface of the pixel electrode 4120 so as to cover the second insulating layer 4144.

In another embodiment, at least a portion of the second insulating layer 4144 may not be covered with the third insulating layer 4145 but may be exposed in a region that corresponds to a portion of the top surface of the pixel electrode 4120.

An intermediate layer 4123 is formed on the top surface of the pixel electrode 4120. The intermediate layer 4123 may include an organic emission layer so as to generate a visible ray. Colors of light that is generated by the intermediate layer 4123 may vary. That is, the colors may include red color, green color, blue color, or the like. In another embodiment, the intermediate layer 4123 may generate white color.

In an embodiment, the organic emission layer of the intermediate layer 4123 may be commonly formed in the pixels P1, P2, and P3 as shown in FIG. 11. The intermediate layer 4123 may generate common visible light, e.g., white light. To do so, the intermediate layer 4123 may have a structure in which red, green, and blue organic emission layers are stacked, and in another embodiment, the intermediate layer 4123 may have a structure in which red, green, and blue organic emission layer materials are mixed as a single layer. Also, the aforementioned colors are exemplary examples and color combinations may vary.

An opposite electrode 4122 is formed on the intermediate layer 4123. The opposite electrode 4122 may be formed of various conductive materials. The opposite electrode 4122 may be commonly formed in the pixels P1, P2, and P3.

The photo-protective layer 4105 may correspond to the active layer 4130. The photo-protective layer 4105 may face a surface of the active layer 4130 that is opposite to another surface of the active layer 4130 that faces the gate electrode 4140.

In another embodiment, an over-coated layer 4103 may be formed on the substrate 4101 so as to cover the photo-protective layer 4105. The over-coated layer 4103 may be formed below the buffer layer 4102.

The color filters 4106R, 4106G, 4106B respectively correspond to at least portions of the respective pixel electrodes 4120. In more detail, each of the portions overlaps the intermediate layer 4123, and the color filters 4106R, 4106G, 4106B may respectively correspond to said portions.

The color filters 4106R, 4106G, 4106B may convert lights into different colors, respectively, wherein the lights are generated by the intermediate layer 4123. For example, the color filters 4106R, 4106G, 4106B may convert lights, which are generated by the intermediate layer 4123, into red, green, and blue visible lights.

The red, green, and blue colors are exemplary color combinations, and various color combinations may be used for the display apparatus 4000 that is capable of realizing various colors. To do so, the display apparatus 4000 may include various color filters capable of converting lights, which are generated by the intermediate layer 4123, into various colors.

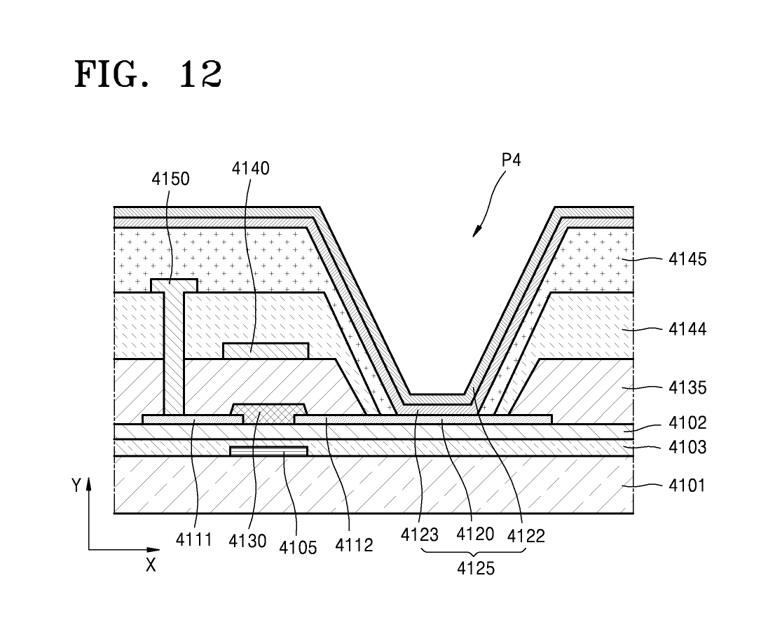

In an embodiment, the display apparatus 4000 may include a pixel in which the color filters 4106R, 4106G, 4106B are not arranged. FIG. 12 is a schematic view illustrating a modified example of the display apparatus 4000 of FIG. 11.

Referring to FIG. 12, the display apparatus 4000 may include a pixel P4 in which the color filters 4106R, 4106G, 4106B are not arranged. In the pixel P4, light that is generated by the intermediate layer 4123 is changelessly extracted without an affect by the color filters 4106R, 4106G, 4106B, e.g., white visible light may be extracted.

Referring back to FIG. 11, the color filters 4106R, 4106G, 4106B may be disposed between the pixel electrode 4120 and the substrate 4101.

In an embodiment, the color filters 4106R, 4106G, 4106B may be formed on the substrate 4101, and the over-coated layer 4103 may be formed to cover the color filters 4106R, 4106G, 4106B. The over-coated layer 4103 may be formed below the buffer layer 602.

The color filters 4106R, 4106G, 4106B may be formed to correspond to the pixel electrodes 3120, respectively, so that the display apparatus 3000 that generates various colors may be easily embodied.

When the color filters 4106R, 4106G, 4106B are formed, the photo-protective layer 4105 may be simultaneously formed by using a red color filter material of the color filter 4106R.

That is, after the photo-protective layer 4105 and the color filters 4106R, 4106G, 4106B are formed on the substrate 4101, the over-coated layer 4103 may be formed to cover the photo-protective layer 4105 and the color filters 4106R, 4106G, 4106B.

By doing so, manufacturing efficiency of the display apparatus 4000 may be improved.

In the present embodiment, the display apparatus 4000 may have a structure in which the source electrode 4111 and the drain electrode 4112 are formed on the substrate 4101, and the pixel electrode 4120 extends from any one of the source electrode 4111 and the drain electrode 4112. That is, since the pixel electrode 4120 is formed of the same material as the source electrode 4111 and the drain electrode 4112, manufacturing efficiency may be improved.

Also, the source electrode 4111, the drain electrode 4112, and the pixel electrode 4120 may be formed of the light-transmitting material, and by doing so, light may pass through the pixel electrode 4120, thus, the display apparatus 4000 that realizes an image toward the substrate 4101 may be easily embodied.

Also, since the auxiliary electrode 4150 is formed to be electrically connected to one of the source electrode 4111 and the drain electrode 4112, an electrical characteristic of the source electrode 4111 and the drain electrode 4112 may be improved, and the display apparatus 4000 having an excellent electrical characteristic may be easily embodied.

In the present embodiment, the display apparatus 3000 may prevent, by arranging the photo-protective layer 4105, the active layer 4130 from being damaged by light, so that the display apparatus 3000 having an improved electrical characteristic may be easily embodied.

In the present embodiment, the display apparatus 4000 may prevent, by arranging the photo-protective layer 4105, the active layer 4130 from being damaged by light, so that the display apparatus 4000 having an improved electrical characteristic may be easily embodied.

Also, since the source electrode 4111 and the drain electrode 4112 are formed on the substrate 4101, and the active layer 4130 is formed on the source electrode 4111 and the drain electrode 4112, overlapping regions or contact regions between the active layer 4130 and the source electrode 4111 and the drain electrode 4112 are increased, so that a short channel structure may be easily implemented. By doing so, the display apparatus 4000 having high definition may be easily embodied.

Also, when the intermediate layer 4123 is selectively formed, the intermediate layer 4123 is commonly formed in all selected pixels, so that manufacturing efficiency of the display apparatus 4000 may be improved.

Although not illustrated, a display apparatus having the structure of one of FIGS. 2, 3, 4, and 5 may also be embodied.

As described above, the thin film transistor substrate and the display apparatus according to the one or more of the above exemplary embodiments may easily improve an electrical characteristic and manufacturing efficiency of the display apparatus.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims.

1. A thin film transistor substrate, comprising:
a substrate;
a source electrode and a drain electrode disposed on the substrate;
an active layer formed on the source electrode and the drain electrode;
a gate electrode formed on and insulated from the active layer; and
a pixel electrode that extends in a same plane from one of the source electrode and the drain electrode.

2. The thin film transistor substrate of claim 1, further comprising an auxiliary electrode electrically connected to one of the source electrode and the drain electrode.

3. The thin film transistor substrate of claim 2, the auxiliary electrode contacting a top surface of one of the source electrode and the drain electrode.

4. The thin film transistor substrate of claim 2, the auxiliary electrode being formed of a material having a lower resistivity than the source electrode and the drain electrode.

5. The thin film transistor substrate of claim 2, the auxiliary electrode being separate from the active layer.

6. The thin film transistor substrate of claim 2, further comprising a first insulating layer disposed on the gate electrode, and
the auxiliary electrode being disposed on the first insulating layer.

7. The thin film transistor substrate of claim 1, further comprising a protective layer formed on a surface of the active layer that faces the gate electrode.

8. The thin film transistor substrate of claim 1, further comprising a photo-protective layer disposed between the active layer and the substrate and at least partially overlaps the active layer.

9. The thin film transistor substrate of claim 8, the photo-protective layer being formed of a color filter material

10. The thin film transistor substrate of claim 1, further comprising a color filter disposed between the pixel electrode and the substrate and at least partially overlaps the pixel electrode.

11. A display apparatus, comprising:
a substrate;
a source electrode and a drain electrode disposed on the substrate;
an active layer formed on the source electrode and the drain electrode;
a gate electrode formed on and insulated from the active layer; and
a display device realizing at least one visible light,
the display device comprising a pixel electrode that extends in a same plane from one of the source electrode and the drain electrode.

12. The display apparatus of claim 11, further comprising an auxiliary electrode electrically connected to one of the source electrode and the drain electrode.

13. The display apparatus of claim 11, further comprising a protective layer formed on a surface of the active layer that faces the gate electrode.

14. The display apparatus of claim 11, further comprising a photo-protective layer disposed between the active layer and the substrate and at least partially overlaps the active layer.

15. The display apparatus of claim 11, further comprising a color filter disposed between the pixel electrode and the substrate and at least partially overlaps the pixel electrode.

16. The display apparatus of claim 11, the display device comprising:
an opposite electrode facing the pixel electrode; and
an intermediate layer disposed between the pixel electrode and the opposite electrode and comprising an organic emission layer.

17. A display apparatus comprising a plurality of pixels that are formed on a substrate, each of the plurality of pixels comprising a thin-film transistor and a display device that realizes at least one visible light,
the thin-film transistor comprising:
a source electrode and a drain electrode;
an active layer formed on the source electrode and the drain electrode; and
a gate electrode formed on and insulated from the active layer, and
the display device comprising a pixel electrode that extends in a same plane from one of the source electrode and the drain electrode.

18. The display apparatus of claim 17, the display device comprising:
an opposite electrode facing the pixel electrode; and
an intermediate layer disposed between the pixel electrode and the opposite electrode and comprising an organic emission layer.

19. The display apparatus of claim 18, the organic emission layer of the intermediate layer being commonly formed in two adjacent pixels from among the plurality of pixels.

20. The display apparatus of claim 18, the intermediate layer generating visible light is common with respect to the plurality of pixels.
